(19) United States
(12) Patent Application Publication
(10) Pub. No.: US 2006/0170466 A1
(43) Pub. Date: Aug. 3, 2006

(54) Adjustable start-up circuit for switching regulators

(76) Inventor: Sangbeom Park, Tracy, CA (US)

Correspondence Address: Kieun Park;DBA ANA Semiconductor, P.O. Box 65, Tracy, CA, 95376, US

(21) Appl. No.: 11/048,260

(22) Filed: Jan. 31, 2005

(51) Int. Cl. H03L 7/00

(52) U.S. Cl. 327/143

(57) ABSTRACT

The adjustable start-up circuits basically include a sensor, a reference voltage, two stacked PMOS transistors, two stacked NMOS transistors, and a feedback line. The sensor compares a feedback voltage with a reference voltage. If the sensing voltage does not reach the reference voltage, the output voltage of the sensor turns on the corresponding transistor, which provides a current to its output until the voltage at feedback reaches the reference voltage. The time to reach the expected output voltage level at a load is simply equal to the charge stored at the load divided by the current, which can be scaled by a device aspect ratio of the transistor. Consequently, all adjustable start-up circuits provide an adjustable initial output voltage level closer to the output voltage level that reaches the equilibrium according to schedule. In addition, the output voltage level is varied by changing the reference voltage level.

### FIELD OF THE INVENTION

The present invention relates to the field of switching regulator and more particularly to adjustable start-up circuit for switching regulators.

### BACKGROUND ART

Switching regulator is a vitally important device. Switching regulators are building blocks used extensively in power systems, industry, motor, communication, networks, digital systems, consumer electronics, computers, and any other fields that require high efficient voltage regulating functions.

Switching regulators (i.e., DC-TO-DC converters) can provide output voltages which can be less than, greater than, or of opposite polarity to the input voltage. Prior Art FIG. 1 illustrates a basic architecture of a conventional switching regulator 100. The conventional switching regulator 100 basically consists of an oscillator, a reference circuit 102, an error amplifier, a modulator, resistors, and a control logic circuit. It is noted that the modulator includes a comparator. Control technique of switching regulators has typically used two modulators: a pulse-width modulator and a pulse-frequency modulator. The output DC level is sensed through the feedback loop including two resistors. An error amplifier compares two input voltages: the sampled output voltage and the reference voltage. In addition, the output of the error amplifier is compared against a periodic ramp generated by the saw tooth oscillator. The pulse-width modulator output passes through the control logic to the power switch. The feedback system regulates the current transfer to maintain a constant output voltage within the load limits. In other words, it insures that the output voltage level reaches the equilibrium. When the output voltage level reaches the equilibrium, V_{F} is equal to V_{REF}, as shown in Prior Art FIG. 1.

However, it takes a vast amount of time until the output voltage level reaches the equilibrium from an initial condition after the switching regulator of Prior Art FIG. 1 starts. Therefore, power and time are consumed until the switching regulator's output voltage level reaches the equilibrium. In addition, it takes a long time to simulate and verify the conventional switching regulator 100 before fabrication since its simulation time is absolutely proportional to time that is required the switching regulator's output voltage level to reach the equilibrium. Hence, this long simulation adds additional cost and serious bottleneck to design time-to-market. In other words, the slow start-up of the switching regulator increases design simulation time. For these reasons, the conventional switching regulator 100 of Prior Art FIG. 1 is very inefficient to implement in system-on-chip (SOC) or integrated circuit (IC).

Thus, what is needed is a fast starting-up switching regulator that can be highly efficiently implemented with a drastic improvement in a very fast start-up time, start-up time controllability, adjustable initial level, performance, time-to-market, power consumption, power and time management, efficiency, cost, and design time. It is highly desirable to enable all of the switching regulators' output voltage levels to reach the equilibrium immediately for much higher power efficiency or according to schedule. The present invention satisfies these needs by providing five embodiments.

### SUMMARY OF THE INVENTION

The present invention provides five types of the adjustable start-up circuits for switching regulators. The adjustable start-up circuits simultaneously enable any switching regulator's output voltage level to reach the equilibrium according to schedule. In addition, the output voltage level is varied by changing the reference voltage level. The basic architecture of the adjustable start-up circuits consists of a sensor, a reference voltage, two stacked PMOS transistors, two stacked NMOS transistors, and a feedback line. The sensor compares a feedback voltage with a reference voltage. If the sensing voltage does not reach the reference voltage, the output voltage of the sensor turns on the corresponding transistor, which provides a current to its output until the output voltage reaches the reference voltage. The time to reach the expected output voltage level is simply equal to the charge stored at the load divided by the current, which can be scaled.

Consequently, all adjustable start-up circuits provide a significant reduction in the difference between the initial output voltage level and the expected output voltage level in order to overcome serious drawbacks simultaneously. The adjustable start-up time of the present invention enables all systems to be managed in terms of power, stand-by time, and start-up time. The present invention provides five different embodiments which achieve a drastic improvement in a very fast start-up time, start-up time controllability, adjustable initial level, performance, time-to-market, power consumption, power and time management, efficiency, cost, and design time.

### BRIEF DESCRIPTION OF THE DRAWINGS

The accompanying drawings, which are incorporated in and form a part of this specification, illustrate five embodiments of the invention and, together with the description, serve to explain the principles of the invention:

Prior Art FIG. 1 illustrates a block diagram of a conventional switching regulator (i.e., DC-TO-DC converter).

FIG. 2 illustrates a block diagram of two types of adjustable start-up circuits for switching regulator in accordance with the present invention.

FIG. 3 illustrates a circuit diagram of a basic adjustable start-up circuit according to the present invention.

FIG. 4 illustrates a circuit diagram of an adjustable start-up circuit in accordance with the present invention.

FIG. 5 illustrates a circuit diagram of a dual adjustable start-up circuit according to the present invention.

FIG. 6 illustrates a circuit diagram of a p-type adjustable start-up circuit in accordance with the present invention.

FIG. 7 illustrates a circuit diagram of a p-type dual adjustable start-up circuit according to the present invention.

### DESCRIPTION OF THE PREFERRED EMBODIMENTS

In the following detailed description of the present invention, five types of the adjustable start-up circuits, numerous specific details are set forth in order to provide a thorough understanding of the present invention. However, it will be obvious to one skilled in the art that the present invention may be practiced without these specific details. In other instances, well known methods, procedures, CMOS digital gates, components, and metal-oxide-semiconductor field-effect transistor (MOSFET) device physics have not been described in detail so as not to unnecessarily obscure aspects of the present invention.

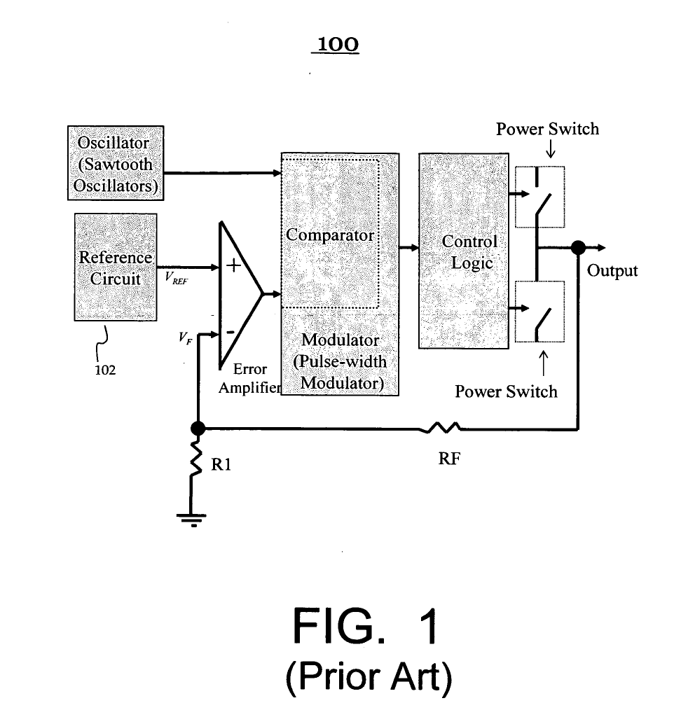

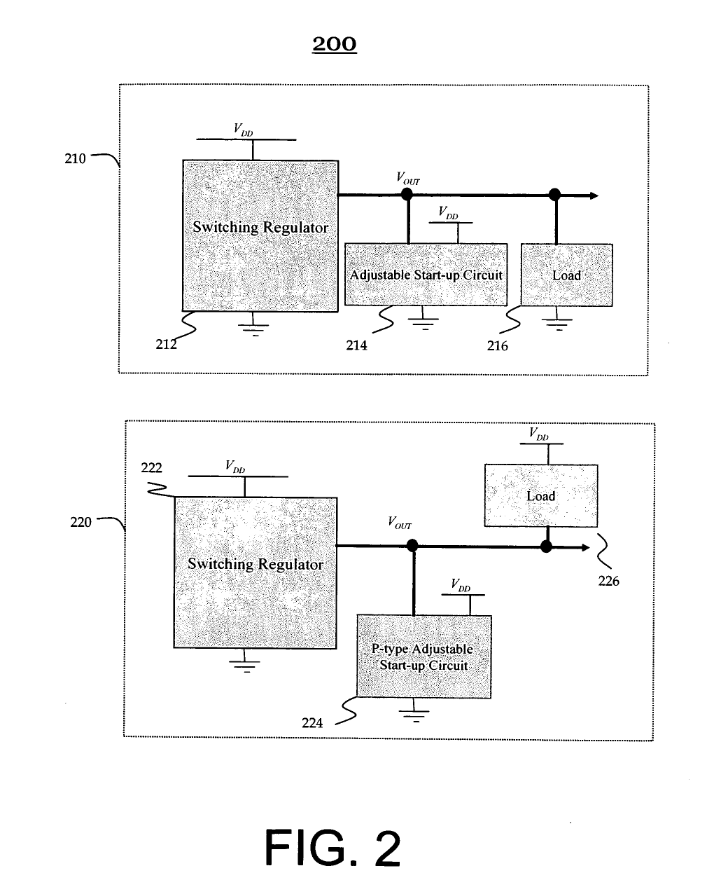

FIG. 2 illustrates two types of the adjustable start-up circuits for switching regulators in accordance with the present invention. One type of the adjustable start-up circuit is applied for switching regulators driving a load 216 connected between V_{OUT} and ground, as seen in the switching regulator system 210 shown in FIG. 2. The other type of the adjustable start-up circuit called “p-type adjustable start-up circuit” is applied for switching regulators driving a load 226 connected between V_{DD} and V_{OUT}, as seen in the switching regulator system 220 shown in FIG. 2. To reduce the difference between the initial output voltage level and the expected output voltage level of the switching regulator, the output of all the adjustable start-up circuits is coupled to the output terminal of switching regulators, as shown in FIG. 2. The switching regulator 212 represents all types of the switching regulators (i.e., DC-TO-DC converter) driving a load 216 connected between V_{OUT} and ground without regard to the types of switching regulators because the applications of the adjustable start-up circuit 214 are independent of architectures and types of switching regulators. The switching regulator 222 represents all types of the switching regulators (i.e., DC-TO-DC converter) driving a load 226 connected between V_{DD} and V_{OUT} without regard to the types of switching regulators because the applications of the p-type adjustable start-up circuit 224 are independent of architectures and types of switching regulators. If loads 216 and 226 are multiple-order, then they will be approximated to the first-order load with neglecting resistor and inductor in the load for simplicity.

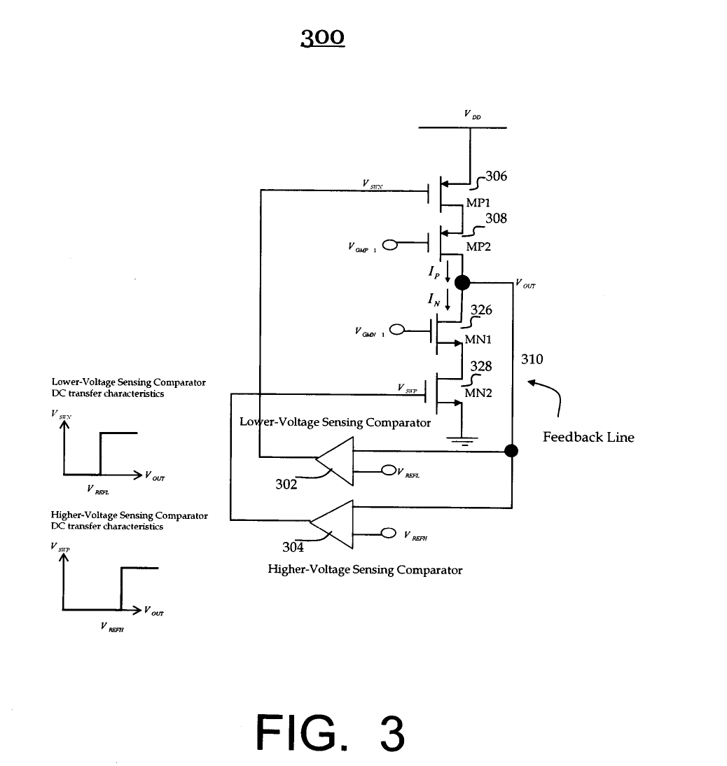

FIG. 3 illustrates a basic adjustable start-up circuit according to the present invention. This basic adjustable start-up circuit 300 does not have power-down mode in order to show the fundamental concept of the invention clearly. The basic adjustable start-up circuit 300 is a feedback circuit that consists of a lower-voltage sensing comparator 302, a higher-voltage sensing comparator 304, two references voltages, two stacked PMOS transistors 306 and 308, two stacked NMOS transistors 326 and 328, and a feedback line 310. The gate terminal of a PMOS transistor 308 is connected to a proper fixed-bias voltage (not shown) or ground (e.g., “0”, low, etc.). The gate terminal of a NMOS transistor 326 is connected to a proper fixed-bias voltage (not shown) or power supply voltage (e.g., V_{DD}, “1”, high, etc.).

It is assumed that the output of the basic adjustable start-up circuit 300 is at ground. Since the lower-voltage sensing comparator 302 initially senses a voltage less than the lower reference voltage, the output voltage of the lower-voltage sensing comparator 302 is low enough to turn on the PMOS transistor 306. At the same time, the output voltage of the higher-voltage sensing comparator 304 is low enough to turn off the NMOS transistor 328. Thus, the PMOS transistor 306 provides a current (i.e., I_{P}) to the output until the output voltage (i.e., V_{OUT}) goes up to the lower reference voltage. The time to reach the expected voltage level at the load connected between V_{OUT} and ground is as follows:

$$Δ t = \frac{{V}_{REFL} {C}_{P}}{{I}_{P}}$$

where V_{REFL} is the lower reference voltage and C_{P} is the value of the capacitor in the load. Also, assuming that V_{REFL} is closer to the output voltage level that reaches the equilibrium in switching regulators, the start-up time of the switching regulators is approximately given by

$$\frac{{V}_{REFL} {C}_{P}}{{I}_{P}}$$

This start-up time is varied by the current I_{P} depending on the size of the PMOS transistor 306.

Now it is differently assumed that the output of the basic adjustable start-up circuit 300 is at power supply. Since the higher-voltage sensing comparator 304 initially senses a voltage greater than the higher reference voltage, the output voltage of the higher-voltage sensing comparator 304 is high enough to turn on the NMOS transistor 328. At the same time, the output voltage of the lower-voltage sensing comparator 302 is high enough to turn off the PMOS transistor 306. Thus, the NMOS transistor 328 provides a current (i.e., I_{N}) to the output until the output voltage (i.e., V_{OUT}) goes down to the higher reference voltage. The time to reach the expected output voltage level at the load connected between V_{OUT} and power supply is as follows:

$$Δ t = \frac{( {V}_{DD} - {V}_{REFH} ) {C}_{P}}{{I}_{N}}$$

where V_{REFH} is the higher reference voltage and C_{P} is the value of the capacitor in the load. Also, assuming that V_{REFH} is closer to the output voltage level that reaches the equilibrium in switching regulators, the start-up time of the switching regulators is approximately given by

$$\frac{( {V}_{DD} - {V}_{REFH} ) {C}_{P}}{{I}_{N}}$$

This start-up time is varied by the current I_{N} depending on the size of the NMOS transistor 328.

In design of the basic adjustable start-up circuit of FIG. 3, it is also desirable to use a value for the lower reference voltage (i.e., V_{REFL}) less than V′_{OUT} and a value for the higher reference voltage (i.e., V_{REFH}) greater than V′_{OUT}. V′_{OUT} is the output voltage level that reaches the equilibrium in switching regulators.

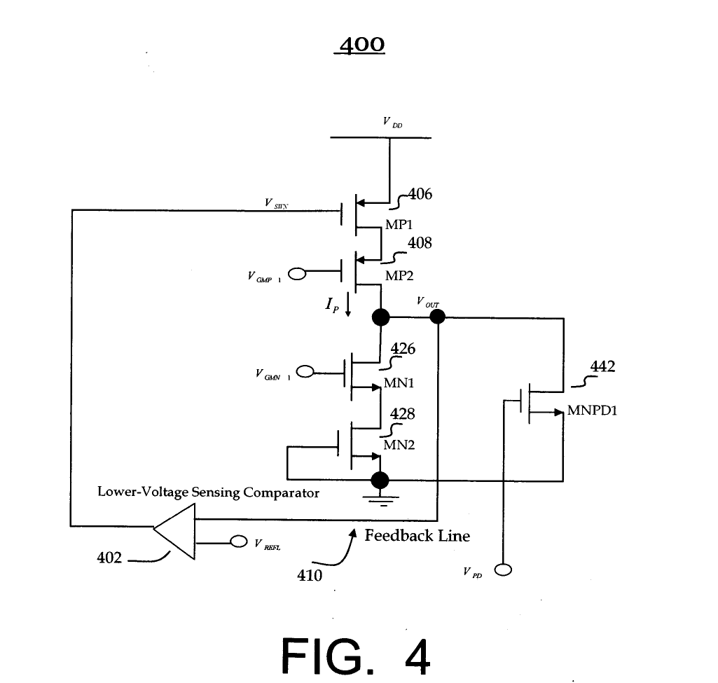

FIG. 4 illustrates an adjustable start-up circuit 400 according to the present invention. A power-down input voltage, V_{PD}, is defined as the input voltage for power-down mode. The power-down enable system is in power-down mode when V_{PD} is V_{DD} and it is in normal mode when V_{PD} is zero. The adjustable start-up circuit 400 is a feedback circuit that consists of a lower-voltage sensing comparator 402, a references voltage, two stacked PMOS transistors 406 and 408, two stacked NMOS transistors 426 and 428, a feedback line 410, and a power-own NMOS transistor 442. In addition, the gate terminal of a PMOS transistor 408 is connected to a proper fixed-bias voltage (not shown) or ground (e.g., “0”, low, etc.). The gate terminal of a NMOS transistor 426 is connected to a proper fixed-bias voltage (not shown) or power supply voltage (e.g., V_{DD}, “1”, high, etc.). Furthermore, the gate terminal of a NMOS transistor 428 is shorted and thus no current flows into the drains of the NMOS transistors 426 and 428.

The circuit mode changes from power-down mode to normal mode in FIG. 4. Since the lower-voltage sensing comparator 402 initially senses a voltage less than the lower reference voltage, the output voltage of the lower-voltage sensing comparator 402 is low enough to turn on the PMOS transistor 406. The PMOS transistor 406 generates a current (i.e., I_{P}) to the output until the output voltage (i.e., V_{OUT}) goes up to the lower reference voltage. Furthermore, assuming that V_{REFL} is closer to the output voltage level that reaches the equilibrium in switching regulators, the start-up time of the switching regulators is approximately given by

$$\frac{{V}_{REFL} {C}_{P}}{{I}_{P}}$$

Also, V_{REFL} is the lower reference voltage and C_{P} is the value of the capacitor in the load. The start-up time is varied by the current I_{P} depending on the size of the PMOS transistor 406.

In design of the adjustable start-up circuit of FIG. 4, it is also desirable to use a value for the lower reference voltage (i.e., V_{REFL}) less than V′_{OUT}. V′_{OUT} is the output voltage level that reaches the equilibrium in switching regulators. The adjustable start-up circuit 400 is used for all types of switching regulators driving the load connected between V_{OUT} and ground. Since the power-down NMOS transistor 442 is on during power-down mode, it provides an output pull-down path to ground. Thus, V_{OUT} of the adjustable start-up circuit 400 is zero so that no current flows into the circuits during power-down mode.

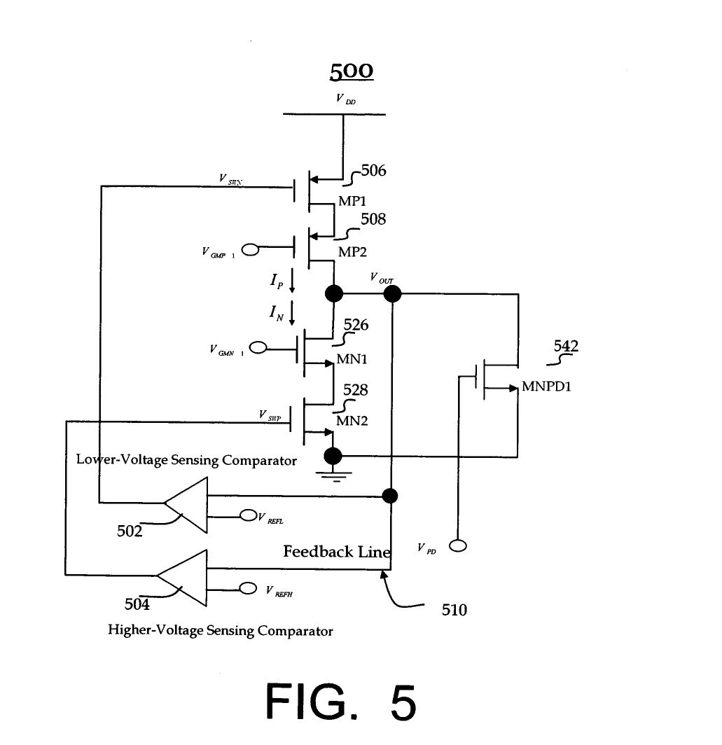

FIG. 5 illustrates a dual adjustable start-up circuit 500 in accordance with the present invention. The dual adjustable start-up circuit 500 is a modification of the circuit described in FIG. 4. The gate terminal of a PMOS transistor 508 is connected to a proper fixed-bias voltage (not shown) or ground (e.g., “0”, low, etc.). The gate terminal of a NMOS transistor 526 is connected to a proper fixed-bias voltage (not shown) or power supply voltage (e.g., V_{DD}, “1”, high, etc.). Furthermore, compared to FIG. 4, the first difference to note is that the higher-voltage sensing comparator 504 is added into FIG. 5 in order to provide the higher-voltage sensing function. The second difference to note is that the output of the higher-voltage sensing comparator 504 is connected to the gate terminal of a NMOS transistor 528. Therefore, the dual adjustable start-up circuit 500 is able to sense the lower-voltage as well as the higher-voltage while the adjustable start-up circuit 400 is able to sense only the lower-voltage.

No current flows into the drains of the NMOS transistors 526 and 528 assuming V_{OUT}<V_{REFH} where V_{REFH} is the higher reference voltage. If V_{OUT} is greater than V_{REFH}, the gate of the NMOS transistor 528 is high (e.g., at V_{DD}, “1”, etc.). As a result, a current flows into the drains of the NMOS transistors 526 and 521 until V_{OUT} goes down to the higher reference voltage.

In design of the dual adjustable start-up circuit of FIG. 5, it is also desirable to use a value for the lower reference voltage (i.e., V_{REFL}) less than V′_{OUT} and a value for the higher reference voltage (i.e., V_{REFH}) greater than V′_{OUT}. V′_{OUT} is the output voltage level that reaches the equilibrium in switching regulators. The dual adjustable start-up circuit 500 is used for all types of switching regulators driving the load connected between V_{OUT} and ground. Zero dc volt at V_{OUT} ensures that no current flows into the circuits during power-down mode.

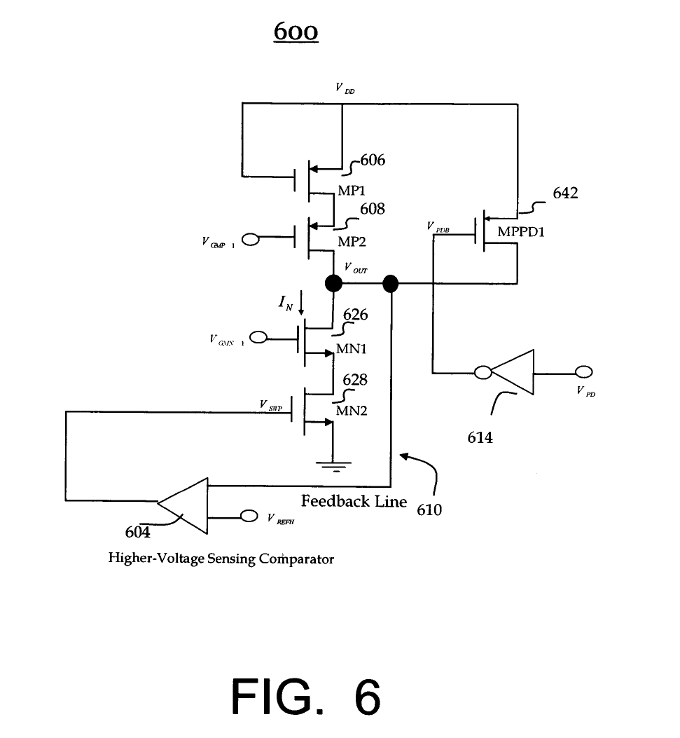

FIG. 6 illustrates a p-type adjustable start-up circuit 600 according to the present invention. The power-down input voltage, V_{PD}, is defined as the input voltage for the p-type power-down mode as well as for the power-down mode. The p-type power-down enable system is in power-down mode when V_{PD} is V_{DD} and it is in normal mode when V_{PD} is zero. The p-type adjustable start-up circuit 600 is a feedback circuit that consists of a higher-voltage sensing comparator 604, a references voltage, two stacked PMOS transistors 606 and 608, two stacked NMOS transistors 626 and 628, a feedback line 610, a power-down inverter 614, and a power-down PMOS transistor 642. In addition, the gate terminal of a PMOS transistor 608 is connected to a proper fixed-bias voltage (not shown) or ground (e.g., “0”, low, etc.). The gate terminal of a NMOS transistor 626 is connected to a proper fixed-bias voltage (not shown) or power supply voltage (e.g., V_{DD}, “1”, high, etc.). Furthermore, since the PMOS transistor 606 is turned off, no current flows out of the drains of the PMOS transistors 606 and 608.

The circuit mode changes from p-type power-down mode to normal mode in FIG. 6. Since the higher-voltage sensing comparator 604 initially senses a voltage greater than the higher reference voltage (i.e., V_{REFH}), the output voltage of the higher-voltage sensing comparator 604 is high enough to turn on the NMOS transistor 628. The NMOS transistor 628 generates a current (i.e., I_{N}) to the output until the output voltage (i.e., V_{OUT}) goes down to V_{REFH}. Assuming that V_{REFH} is closer to the output voltage level that reaches the equilibrium in switching regulators, the start-up time of the switching regulators is approximately given by

$$\frac{( {V}_{DD} - {V}_{REFH} ) {C}_{P}}{{I}_{N}}$$

Also, C_{P} is the value of the capacitor in the load. The start-up time is varied by the current I_{N} depending on the size of the NMOS transistor 628.

In design of the p-type adjustable start-up circuit of FIG. 6, it is also desirable to use a value for the higher reference voltage (i.e., V_{REFH}) greater than V′_{OUT}. V′_{OUT} is the output voltage level that reaches the equilibrium in switching regulators. The p-type adjustable start-up circuit 600 is used for all types of switching regulators driving the load connected between V_{OUT} and power supply. The output voltage of the power-down inverter 614, V_{PDB}, is zero during power-down mode. As a result, the power-down PMOS transistor 642 is turned on and thus provides an output pull-up path to V_{DD}. Therefore, V_{OUT} of the p-type adjustable start-up circuit 600 is V_{DD} so that no current flows into the circuits during power-down mode. On the contrary, it was stated earlier that V_{OUT} must be zero when power-down mode occurs in FIG. 4 and FIG. 5.

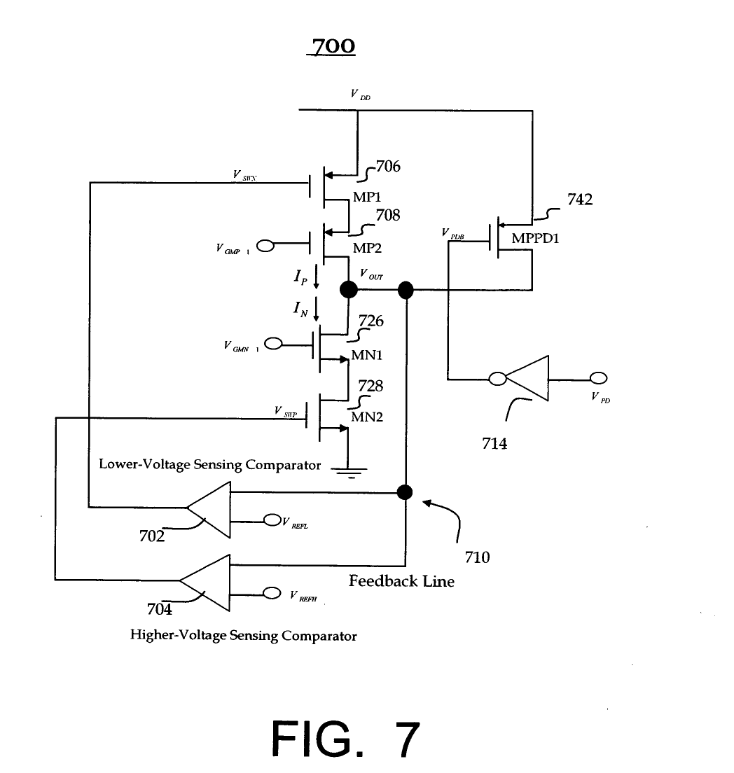

FIG. 7 illustrates a p-type dual adjustable start-up circuit 700 in accordance with the present invention. The p-type dual adjustable start-up circuit 700 is a modification of the circuit described in FIG. 6. The gate terminal of a PMOS transistor 708 is connected to a proper fixed-bias voltage (not shown) or ground (e.g., “0”, low, etc.). The gate terminal of a NMOS transistor 726 is connected to a proper fixed-bias voltage (not shown) or power supply voltage (e.g., V_{DD}, “1”, high, etc.). Compared to FIG. 6, the first difference to note here is that the lower-voltage sensing comparator 702 is added into FIG. 7 in order to sense the lower-voltage. The second difference to note here is that the output of the lower-voltage sensing comparator 702 is connected to the gate terminal of the PMOS transistor 706. The p-type dual adjustable start-up circuit 700 is able to sense the lower-voltage as well as the higher voltage while the p-type adjustable start-up circuit 600 is able to sense only the higher voltage.

No current flows out of the drains of the PMOS transistors 706 and 708 if the output voltage (i.e., V_{OUT}) is greater than the lower reference voltage (i.e., V_{REFL}). If the output voltage is less than the lower reference voltage, the PMOS transistor 706 is turned on until the output voltage goes up to the lower reference voltage. In design of the p-type dual adjustable start-up circuit of FIG. 7, it is also desirable to use a value for the higher reference voltage (i.e., V_{REFH}) greater than V′_{OUT}, and a value for the lower reference voltage (i.e., V_{REFL}) less than V′_{OUT}. V′_{OUT} is the output voltage level that reaches the equilibrium in switching regulators. The p-type dual adjustable start-up circuit 700 is used for all types of switching regulators driving the load connected between V_{OUT} and power supply. V_{OUT}=V_{DD} in the p-type dual adjustable start-up circuit 700 ensures that no current flows into the circuits during power-down mode.

In summary, the five adjustable start-up circuits of the present invention within switching regulators simply control how fast the output voltage level reaches the equilibrium from an adjustable initial output voltage level. In addition, the switching regulator's output voltage level is varied by changing the value of reference voltage. The reference voltage is programmable to provide any expected voltage level for different level applications. Two approaches for realizing the programmable reference voltages are as follows: 1. The reference voltages are outputs of any digital-to-analog converter whose digital data inputs are programmed. 2. The reference voltages are based on selecting taps of a segmented resistor string by a digital circuit that is coupled to the segmented resistor string. The digital circuit consists of the switch (e.g., multiplexer, transmission-gate, MOS transistor) network that is connected in a tree-like decoder or it consists of a decoder and switches. The digital inputs of the digital circuit are programmed. Furthermore, the CMOS process variations usually must be considered so that the proper value of the reference voltage is chosen for all the adjustable start-up circuits 300, 400, 500, 600, and 700. Each bulk of two stacked PMOS transistors can be connected to its own N-well to obtain better immunity from substrate noise in all the adjustable start-up circuits. The balance between PMOS output resistance and NMOS output resistance must be considered to obtain high output resistance.

The adjustable start-up circuit 214 shown in FIG. 2 represents the basic adjustable start-up circuit 300, the adjustable start-up circuit 400, and the dual adjustable start-up circuit 500, as shown in FIG. 3, FIG. 4, and FIG. 5, respectively. Also, the p-type adjustable start-up circuit 224 shown in FIG. 2 represents the basic adjustable start-up circuit 300, the p-type adjustable start-up circuit 600 and the p-type dual adjustable start-up circuit 700, as shown in FIG. 3, FIG. 6, and FIG. 7, respectively. The conventional switching regulator 100 and the switching regulator system 210 including the basic adjustable start-up circuit 300 are simulated using the same components. As a result, the total simulation time of the conventional switching regulator 100 is 40 hours and that of the switching regulator system 210 using

$${( \frac{W}{L} )}_{MP 1} = \frac{6 u}{1 u}$$

of the PMOS transistor 306 is 3 hours. This improvement can be accomplished by simply inserting a proper one of the adjustable start-up circuits into any conventional switching regulator, and the simulation time can be reduced by a factor of 13. It should be noted that the same time step has been used for the SPICE simulation in order to accurately measure and compare the simulation time of all circuits.

All the adjustable start-up circuits of the present invention are very efficient to implement in system-on-chip (SOC) or integrated circuit (IC). The present invention provides five different embodiments which achieve a drastic improvement in a very fast start-up time, start-up time controllability, adjustable initial level, performance, time-to-market, power consumption, power and time management, efficiency, cost, and design time. While the present invention has been described in particular embodiments, it should be appreciated that the present invention should not be construed as being limited by such embodiments, but rather construed according to the claims below.

What is claimed is:

1. An adjustable start-up circuit for enabling the adjustable output voltage level to reach the equilibrium in switching regulator according to schedule, comprising:
a feedback line connected with the output and input of the adjustable start-up circuit and also coupled to a load;
a sensor for comparing a feedback voltage with the reference voltage and providing its output;
two stacked PMOS transistors connected between power supply and the output; and
two stacked NMOS transistors connected between the output and ground.

2. The circuit as recited in claim 1 wherein the sensor is a lower-voltage sensing comparator.

3. The circuit as recited in claim 2 wherein the lower-voltage sensing comparator's output is coupled to the gate terminal of the upper PMOS transistor.

4. The circuit as recited in claim 1 wherein the sensor is a high-voltage sensing comparator.

5. The circuit as recited in claim 4 wherein the high-voltage sensing comparator's output is coupled to the gate terminal of the lower NMOS transistor.

6. The circuit as recited in claim 1 wherein the sensor is both a low-voltage sensing comparator and a high-voltage sensing comparator.

7. The circuit as recited in claim 6 wherein the low-voltage sensing comparator's output is coupled to the gate terminal of the upper PMOS transistor and the high-voltage sensing comparator's output is coupled to the gate terminal of the lower NMOS transistor.

8. The circuit as recited in claim 1 wherein the sensor is operational amplifier.

9. The circuit as recited in claim 1 wherein the sensor is an even number of NAND gates without any reference voltage.

10. The circuit as recited in claim 1 wherein the sensor is an even number of NOR gates without any reference voltage.

11. The circuit as recited in claim 1 further comprising a power-down NMOS transistor so that no current flows into the circuit during power-down mode.

12. The circuit as recited in claim 11 wherein the output of the adjustable start-up circuit is coupled to a load connected between the output and ground.

13. The circuit as recited in claim 11 wherein the output of the adjustable start-up circuit is at ground during power-down mode.

14. The circuit as recited in claim 1 further comprising a power-down PMOS transistor and a power-down inverter so that no current flows into the circuit during power-down mode.

15. The circuit as recited in claim 14 wherein the output of the adjustable start-up circuit is coupled to a load connected between the output and power supply.

16. The circuit as recited in claim 14 wherein the output of the adjustable start-up circuit is at power supply during power-down mode.

17. The circuit as recited in claim 14 wherein a power-down inverter is an odd number of inverters.

18. The circuit as recited in claim 1 wherein the reference voltage is output of any digital-to-analog converter whose digital data inputs are programmed.

19. The circuit as recited in claim 1 wherein the reference voltage is based on selecting tap of a segmented resistor string by a digital circuit that is coupled to the segmented resistor string.

20. The circuit as recited in claim 1 wherein the adjustable start-up circuit is applied to all switching regulators without regard to architectures, topologies, and schematics.
